(19) United States
(12) Patent Application Publication
(10) Pub. No.: US 2009/0015150 A1
(43) Pub. Date: Jan. 15, 2009

(54) Organic light emitting device and method for manufacturing the same

(75) Inventors: Min-Soo Kang, Daejeon Metropolitan City (KR); Se-Hwan Son, Daejeon Metropolitan City (KR); Hyeon Choi, Daejeon Metropolitan City (KR)

Correspondence Address: MCKENNA LONG & ALDRIDGE LLP, 1900 K STREET, NW, WASHINGTON, DC, 20006, US

(73) Assignee: LG CHEM, LTD., Seoul (KR)

(21) Appl. No.: 12/213,488

(22) Filed: Jun. 19, 2008

Related U.S. Application Data
(63) Continuation-in-part of application No. 11/988,219, filed on Jan. 3, 2008.

(30) Foreign Application Priority Data
Jul. 15, 2005 (KR) 10-2005-0064430
Jan. 18, 2008 (KR) 10-2008-0005812

(51) Int. Cl. H01J 1/63; B05D 5/12

(52) U.S. Cl. 313/504; 427/66

(57) ABSTRACT

Disclosed is an organic light emitting device and a method for manufacturing the same. The organic light emitting device includes a first electrode, one or more organic compound layers, and a second electrode. The first electrode includes a conductive layer and an n-type organic compound layer disposed on the conductive layer. A difference in energy between an LUMO energy level of the n-type organic compound layer of the first electrode and a Fermi energy level of the conductive layer of the first electrode is 4 eV or less. One of the organic compound layers interposed between the n-type organic compound layer of the first electrode and the second electrode is a p-type organic compound layer forming an NP junction along with the n-type organic compound layer of the first electrode. A difference in energy between the LUMO energy level of the n-type organic compound layer of the first electrode and an HOMO energy level of the p-type organic compound layer is 1 eV or less. One or more layers interposed between the conductive layer of the first electrode and the second electrode is n-doped with alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal.

This application is a CIP application of U.S. Ser. No. 11/988,218 filed on Jul. 14, 2006 and claims the benefit of the filing date of Korean Patent Application No. 10-2008-0005812 filed on Jan. 18, 2008 in the Korean Intellectual Property Office, the disclosure of which is incorporated herein by reference in its entirety.

### TECHNICAL FIELD

The present invention relates to an organic light emitting device that has a low energy barrier for hole injection from an electrode to an organic compound layer, a low driving voltage, and high efficiency and luminance, and to a method for manufacturing the organic light emitting device. Specifically, the present invention relates to an organic light emitting device, in which an n-type organic compound layer is formed in a hole injection electrode, and at least one layer of organic compound layers is n-doped, and a method for manufacturing the organic light emitting device.

### BACKGROUND ART

In general, an organic light emitting device includes two electrodes and an organic compound layer interposed between the electrodes. In the organic light emitting device, electrons and holes are injected into the organic compound layer from the two electrodes, and a current is converted into visible light. In the organic light emitting device, in order to improve performance, an electron/hole injection layer or an electron/hole transport layer may be further provided, in addition to the organic compound layer for converting the current into visible light.

However, an interface between the electrode formed of metal, metal oxides, or conductive polymers and the organic compound layer is unstable. Accordingly, heat applied from the outside, internally generated heat, or an electric field applied to the device has an adverse effect on performance of the device. Further, a driving voltage for device operation may be increased due to a difference in conductive energy level between the electron/hole injection layer or the electron/hole transport layer and another organic compound layer adjacent thereto. Accordingly, it is important to stabilize an interface between the electron/hole injection layer or the electron/hole transport layer and another organic compound layer and to minimize an energy barrier for injection of electrons/holes from the electrode to the organic compound layer.

The organic light emitting device has been developed so as to adjust a difference of energy level between two or more electrodes and an organic compound layer interposed between the electrodes. In the organic light emitting device, an anode is adjusted to have a Fermi energy level similar to an HOMO (highest occupied molecular orbital) energy level of a hole injection layer or a material having an HOMO energy level similar to a Fermi energy level of an anode is selected for a hole injection layer. However, since the hole injection layer needs to be selected in view of an HOMO energy level of a hole transport layer or a light emitting layer close to the hole injection layer as well as in view of the Fermi energy level of the anode, there is a limitation to select a material for the hole injection layer.

Accordingly, in the method for manufacturing an organic light emitting device, a method of adjusting a Fermi energy level of an anode is adopted. However, a material for the anode is limited.

Meanwhile, it has been known that performance characteristics of a device having multi organic compound layers are affected by transport ability of charge carriers of each organic compound layer. Upon operation, resistance loss to be generated in a charge transport layer is in connection with conductivity, and conductivity has a great effect on a required operation voltage and a thermal load of the device. A band bending phenomenon occurs near a contact point between metal and the organic compound layer according to a concentration of charge carriers of the organic compound layer. With this phenomenon, charge carriers can be easily injected and contact resistance can be reduced.

### DISCLOSURE

### Technical Problem

The present invention has been finalized in view of the drawbacks inherent in the related art, and it is an object of the present invention to provide an organic light emitting device that exhibits excellent performance and has a simplified manufacturing process by reducing an energy barrier for hole injection and improving charge transport ability of a charge transport organic compound layer.

### Technical Solution

An aspect of the present invention provides an organic light emitting device comprising a first electrode, one or more organic compound layers, and a second electrode, wherein the first electrode includes a conductive layer and an n-type organic compound layer disposed on the conductive layer, a difference in energy between an LUMO energy level of the n-type organic compound layer of the first electrode and a Fermi energy level of the conductive layer of the first electrode is 4 eV or less, one of the organic compound layers interposed between the n-type organic compound layer of the first electrode and the second electrode is a p-type organic compound layer forming an NP junction along with the n-type organic compound layer of the first electrode, a difference in energy between the LUMO energy level of the n-type organic compound layer of the first electrode and an HOMO energy level of the p-type organic compound layer is 1 eV or less, and one or more layers interposed between the conductive layer of the first electrode and the second electrode is n-doped with alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal.

Another aspect of the present invention provides a method for manufacturing an organic light emitting device, which includes a first electrode, one or more organic compound layers, and a second electrode. The method comprises forming an n-type organic compound layer on a conductive layer so as to form a first electrode, forming a p-type organic compound layer on the n-type organic compound layer of the first electrode, and forming one or more layers of the organic compound layers by n-doping using alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal.

Hereinafter, the present invention will be specifically described. However, the accompanying drawings and the following detailed description are illustrative but not intended to limit the present invention. Various changes can be made without departing from the scope of the present invention.

An organic light emitting device according to an illustrative embodiment of the present invention includes a first electrode for injecting holes, a second electrode for injecting electrodes, and an organic compound layer having p-type semiconductor characteristics (hereinafter, simply referred to as “p-type organic compound layer”) interposed between the first electrode and the second electrode. The p-type organic compound layer includes a hole injection layer, a hole transport layer or an emitting layer. The organic light emitting device may further include at least one organic compound layer between the p-type organic compound layer and the second electrode. When the organic light emitting device includes a plurality of organic compound layers, the organic compound layers may be formed of the same material or different materials.

The first electrode includes a conductive layer and an organic compound layer having n-type semiconductor characteristics (hereinafter, simply referred to as “n-type organic compound layer”) located on the conductive layer. The conductive layer includes metal, metal oxides, or conductive polymers. The conductive polymer may include electrical conductive polymer. The conductive layer of the first electrode may be formed of the same material as the second electrode.

The n-type organic compound layer has a predetermined LUMO energy level with respect to a Fermi energy level of the conductive layer and an HOMO energy level of the p-type organic compound layer. The n-type organic compound layer of the first electrode is selected such that a difference in energy between the LUMO energy level of the n-type organic compound layer of the first electrode and the Fermi energy level of the conductive layer of the first electrode and a difference in energy between the LUMO energy level of the n-type organic compound layer and the HOMO energy level of the p-type organic compound layer are reduced. Accordingly, holes are easily injected into the HOMO energy level of the p-type organic compound layer through the LUMO energy level of the n-type organic compound layer of the first electrode.

The difference in energy between the LUMO energy level of the n-type organic compound layer of the first electrode and the Fermi energy level of the conductive layer of the first electrode is preferably 4 eV or less (not including 0 eV). In view of material selection, more preferably, the difference in energy is in a range of about 0.01 to 4 eV. The difference in energy between the LUMO energy level of the n-type organic compound layer of the first electrode and the HOMO energy level of the p-type organic compound layer is preferably 1 eV or less (not including 0 eV), and more preferably, is about 0.5 eV or less (not including 0 eV). In view of material selection, more preferably, the difference is in a range of about 0.01 to 1 eV.

If the difference in energy between the LUMO energy level of the n-type organic compound layer of the first electrode and the Fermi energy level of the conductive layer of the first electrode is larger than 4 eV, an effect of a surface dipole or a gap state on an energy barrier for hole injection is reduced. If the difference in energy between the LUMO energy level of the n-type organic compound layer and the HOMO energy level of the p-type organic compound layer is larger than 1 eV, an NP junction between the p-type organic compound layer and the n-type organic compound layer of the first electrode does not easily occur, which causes an increase in driving voltage for hole injection.

The differences in energy between the LUMO energy level of the n-type organic compound layer, and the Fermi energy level of the conductive layer of the first electrode and the HOMO energy level of the p-type organic compound layer are larger than about 0 eV.

FIGS. 1(a) and 1(b) show the energy level of the first electrode before and after application of the n-type organic compound layer to the first electrode for hole injection in the organic light emitting device according to the illustrative embodiment of the present invention. Referring to FIG. 1(a), the conductive layer has a Fermi energy level E_{F1} higher than a Fermi energy level E_{F2} of the n-type organic compound layer. A vacuum level VL represents an energy level at which electrons freely move in the conductive layer and the n-type organic compound layer.

When the organic light emitting device uses the n-type organic compound layer as a portion of the first electrode, the conductive layer comes into contact with the n-type organic compound layer. Referring to FIG. 1(b), since electrons move from the conductive layer to the n-type organic compound layer, the Fermi energy levels E_{F1} and E_{F2} of the two layers are made equal to each other. Consequently, the surface dipole is formed at the interface of the conductive layer and the n-type organic layer, and the vacuum level, the Fermi energy level, the HOMO energy level, and the LUMO energy level are changed as shown in FIG. 1(b).

Accordingly, even though the difference between the Fermi energy level of the conductive layer and the LUMO energy level of the n-type organic compound layer is large, the energy barrier for hole injection can be reduced by bringing the conductive layer into contact with the n-type organic compound layer. Further, when the conductive layer has a Fermi energy level larger than the LUMO energy level of the n-type organic compound layer, electrons move from the conductive layer to the n-type organic compound layer, and a gap state is formed at an interface between the conductive layer and the n-type organic compound layer. Therefore, the energy barrier for electron transport is minimized.

The n-type organic compound layer includes, but not limited to, 2,3,5,6-tetrafluoro-7,7,8,8-tetracyanoquinodimethane (F4TCNQ), fluoro-substituted 3,4,9,10-perylenetetracarboxylic dianhydride (PTCDA), cyano-substituted PTCDA, naphthalene-tetracarboxylic-dianhydride (NTCDA), fluoro-substituted NTCDA, cyano-substituted NTCDA, or hexanitrile hexaazatriphenylene (HAT), which has an LUMO energy level of about 5.24 eV.

The organic light emitting device according to the present invention includes a p-type organic compound layer that comes into contact with the n-type organic compound layer of the first electrode for hole injection. Accordingly, the NP junction is formed in the device. FIG. 2 shows an NP junction formed between the n-type organic compound layer of the first electrode and the p-type organic compound layer.

When the NP junction is formed, the difference in energy level between the LUMO energy level of the n-type organic compound layer of the first electrode and the HOMO energy level of the p-type organic compound layer is reduced. Accordingly, holes or electrons are easily formed by an external voltage or light source. That is, with the NP junction, holes are easily formed in the p-type organic compound layer, and electrons are easily formed in the n-type organic compound layer of the first electrode. Since the holes and electrons are simultaneously formed in the NP junction, the electrons are transported to the conductive layer of the first electrode through the n-type organic compound layer of the first electrode, and the holes are transported to the p-type organic compound layer.

In order to allow the holes to be efficiently transported to the p-type organic compound layer by the NP junction, the difference in energy level between the LUMO energy level of the n-type organic compound layer of the first electrode and the HOMO energy level of the p-type organic compound layer needs to be a predetermined level. Accordingly, the difference between the LUMO energy level of the n-type organic compound layer of the first electrode and the HOMO energy level of the p-type organic compound layer is preferably about 1 eV or less, and more preferably, is about 0.5 eV or less.

In the organic light emitting device according to the present invention, one or more layers of the organic compound layers interposed between the conductive layer of the first electrode and the second electrode are preferably n-doped with alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal. In the present invention, the n-doped organic compound layer may be the n-type organic compound layer as a portion of the first electrode, or may be another organic compound layer. The n-doped organic compound layer is preferably electron injection and/or transport layer.

In the present invention, as described above, a density of charge carriers in the organic compound layer is increased by the organic compound layer n-doped with alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal, thereby improving charge transport efficiency in the device. Specifically, the density of charge carriers in the organic compound layer is significantly increased by doping an appropriate donor material into an electron transport layer (n-doping), and, as a result, the charge conductivity is significantly increased.

Particularly, in the present invention, as described above, with the first electrode having the conductive layer and the n-type organic compound layer, and the p-type organic compound layer forming the NP junction along with the n-type organic compound layer of the first electrode, the energy barrier for hole injection from the first electrode to the organic compound layer can be significantly reduced. Accordingly, hole injection and transport from the first electrode to a light emitting region of the organic light emitting device can be efficiently performed. In the organic light emitting device according to the present invention having high hole injection efficiency as describing above, when the organic compound layer for electron injection and/or transport is n-doped with an organic material or an inorganic material in order to improve electron transport ability, electrons as well as holes may reach the light emitting region of the device at high concentration. Accordingly, the organic light emitting device according to the present invention can exhibit excellent low voltage, high luminance, and high efficiency characteristics.

In the present invention, the material doped into the organic compound layer is alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal. Examples of the alkali earth metal include Be, Mg, Ca, Sr, Ba, Ra, etc. Examples of the alkali metal include Li, Na, K, Rb, Cs, etc. The metal compounds include organic metal complex, metal organic salt, metal inorganic salt, etc.

Electron injection or transport materials can be used as the material of the organic compound layer n-doped with the above material, but it is not limited thereto. For example, the compound having the functional group selected from the group consisting of an imidazole group, an oxazole group, a thiazole group, a quinoline group and a phenanthroline group can be used.

Preferred examples of the compound having the functional group that is selected from the group consisting of the imidazole group, the oxazole group, and the thiazole group include a compound that is represented by the following Formula 1 or 2.

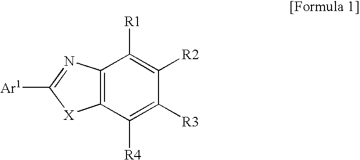

In the above Formula 1, R¹ to R⁴ may be the same or different from each other, are each independently a hydrogen atom; a C₁ to C₃₀ alkyl group that is unsubstituted or substituted with one or more groups selected from the group consisting of a halogen atom, an amino group, a nitrile group, a nitro group, a C₁ to C₃₀ alkyl group, a C₂ to C₃₀ alkenyl group, a C₁ to C₃₀ alkoxy group, a C₃ to C₃₀ cycloalkyl group, a C₃ to C₃₀ heterocycloalkyl group, a C₅ to C₃₀ aryl group, and a C₂ to C₃₀ heteroaryl group; a C₃ to C₃₀ cycloalkyl group that is unsubstituted or substituted with one or more groups selected from the group consisting of a halogen atom, an amino group, a nitrile group, a nitro group, a C₁ to C₃₀ alkyl group, a C₂ to C₃₀ alkenyl group, a C₁ to C₃₀ alkoxy group, a C₃ to C₃₀ cycloalkyl group, a C₃ to C₃₀ heterocycloalkyl group, a C₅ to C₃₀ aryl group, and a C₂ to C₃₀ heteroaryl group; a C₅ to C₃₀ aryl group that is unsubstituted or substituted with one or more groups selected from the group consisting of a halogen atom, an amino group, a nitrile group, a nitro group, a C₁ to C₃₀ alkyl group, a C₂ to C₃₀ alkenyl group, a C₁ to C₃₀ alkoxy group, a C₃ to C₃₀ cycloalkyl group, a C₃ to C₃₀ heterocycloalkyl group, a C₅ to C₃₀ aryl group, and a C₂ to C₃₀ heteroaryl group; or a C₂ to C₃₀ heteroaryl group that is unsubstituted or substituted with one or more groups selected from the group consisting of a halogen atom, an amino group, a nitrile group, a nitro group, a C₁ to C₃₀ alkyl group, a C₂ to C₃₀ alkenyl group, a C₁ to C₃₀ alkoxy group, a C₃ to C₃₀ cycloalkyl group, a C₃ to C₃₀ heterocycloalkyl group, a C₅ to C₃₀ aryl group, and a C₂ to C₃₀ heteroaryl group, and may form an aliphatic, aromatic, aliphatic hetero, or aromatic hetero condensation ring or a spiro bond in conjunction with a neighboring group; Ar¹ is a hydrogen atom, a substituted or unsubstituted aromatic ring or a substituted or unsubstituted aromatic hetero ring; X is O, S, or NR^{a}, and R^{a} is hydrogen, a C₁ to C₇ aliphatic hydrocarbon, an aromatic ring or an aromatic hetero ring.

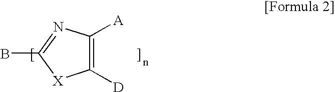

In the above Formula 2, X is O, S, NR^{b} or a C₁ to C₇ divalent hydrocarbon group; A, D, and R^{b} are each a hydrogen atom, a nitrile group (—CN), a nitro group (—NO₂), a C₁ to C₂₄ alkyl, a C₅ to C₂₀ aromatic ring or a hetero-atom substituted aromatic ring, a halogen, or an alkylene or an alkylene containing a hetero-atom that can form a fused ring in conjunction with an adjacent ring; A and D may be connected to each other to form an aromatic or hetero aromatic ring; B is a linkage unit and substituted or unsubstituted alkylene or arylene that conjugately or unconjugately connects multiple hetero rings when n is 2 or more, and substituted or unsubstituted alkyl or aryl when n is 1; and n is an integer in the range of 1 to 8.

Examples of the compound that is represented by the above Formula 1 and used as the compound applied to the above organic substance layer include a compound that is disclosed in Korean Patent Application Publication No. 2003-0067773, and examples of the compound that is represented by the above Formula 2 include a compound that is disclosed in U.S. Pat. No. 5,645,948 and a compound that is disclosed in WO05/097756. The disclosures of above-mentioned documents are incorporated herein by reference in its entirety.

Specifically, the compound that is represented by the above Formula 1 includes the compound that is represented by the following Formula 3.

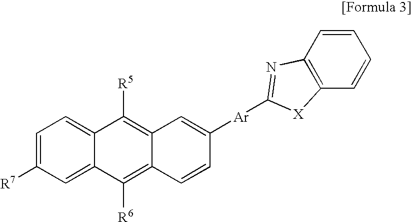

In the above Formula 3, R⁵ to R⁷ are the same or different from each other, are each independently a hydrogen atom, a C₁ to C₂₀ aliphatic hydrocarbon, an aromatic ring, an aromatic hetero ring or an aliphatic or aromatic fused ring; Ar is a direct bond, an aromatic ring, an aromatic hetero ring or an aliphatic or aromatic fused ring; and X is O, S, or NR^{a}, R^{a} is a hydrogen atom, a C₁ to C₇ aliphatic hydrocarbon, an aromatic ring, or an aromatic hetero ring, with a proviso that R⁵ and R⁶ can not simultaneously be hydrogen.

In addition, the compound that is represented by the above Formula 2 includes the compound that is represented by the following Formula 4.

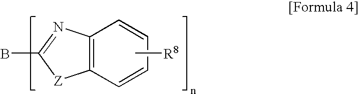

In the above Formula 4, Z is O, S, or NR^{b}, R⁸ and R^{b} are a hydrogen atom, a C₁ to C₂₄ alkyl, a C₅ to C₂₀ aromatic ring or a hetero-atom substituted aromatic ring, a halogen, or an alkylene or an alkylene containing a hetero-atom that can form a fused ring in conjunction with a benzazole ring; B is a linkage unit and alkylene, arylene, substituted alkylene, or substituted arylene that conjugately or unconjugately connects multiple benzazoles when n is 2 or more and substituted or unsubstituted alkyl or aryl when n is 1, and n is an integer in the range of 1 to 8.

Examples of the preferable compound having an imidazole group include compounds having the following structures.

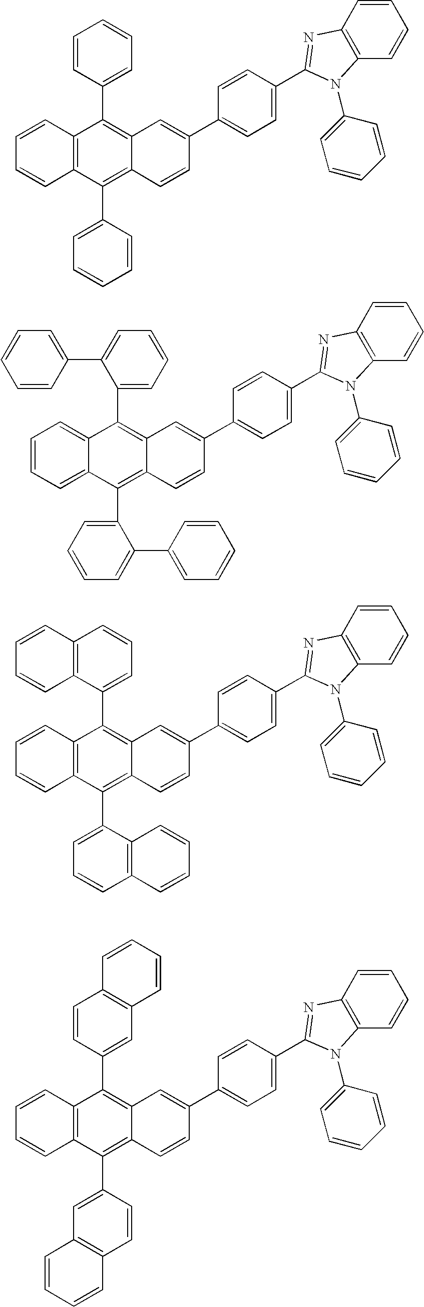

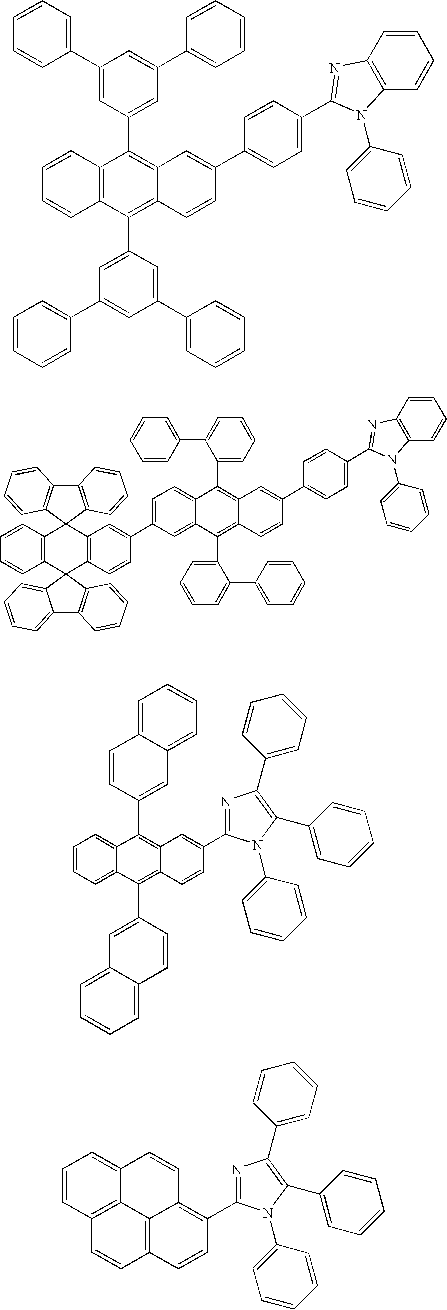

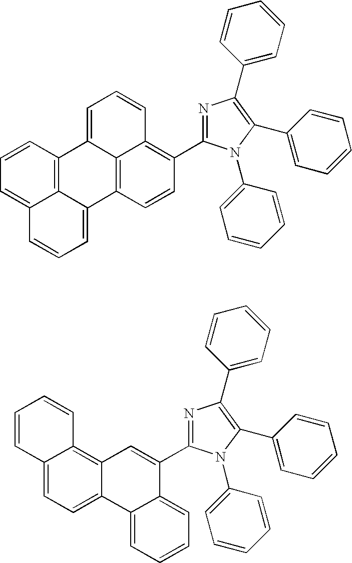

In the present invention, examples of the compound having the quinoline group include compounds that are represented by the following Formulae 5 to 11.

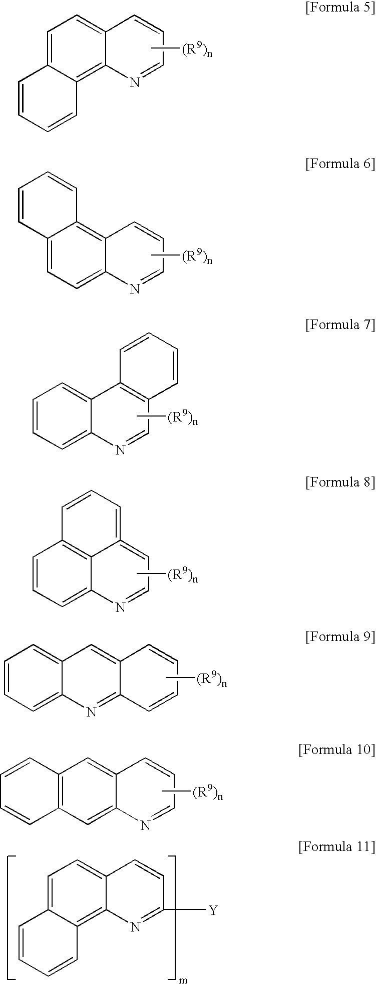

Wherein n is an integer in the range of 0 to 9, m is an integer in the range of 2 or more,

R⁹ is one selected from the group consisting of hydrogen, an alkyl group such as methyl and ethyl, a cycloalkyl group such as cyclohexyl and a norbornyl, an aralkyl group such as benzyl group, an alkenyl group such as vinyl and allyl, a cycloalkenyl group such as cyclopentadienyl and cyclohexenyl, an alkoxy group such as methoxy, an alkylthio group in which an oxygen atom in ether bonding of an alkoxy group is substituted by a sulfur atom, an arylether group such as phenoxy, an arylthioether group in which an oxygen atom in ether bonding of an arylether group is substituted by a sulfur atom, an aryl group such as phenyl, naphthyl and biphenyl, a heterocyclic group such as furyl, thienyl, oxazolyl, pyridyl, quinolyl, carbazolyl, halogen, a cyano group, an aldehyde group, a carbonyl group, a carboxyl group, an ester group, a carbamoyl group, an amino group, a nitro group, a silyl group such as trimethylsilyl, a siloxanyl group having silicon by ether bonding, and a ring structure that is formed in conjunction with an adjacent group; the above substituent groups may be unsubstituted or substituted, and the above substitutent groups are the same or different from each other when n is 2 or more, and

Y is a group having 2 or more valence of the above-mentioned R⁹ groups.

The compounds of Formulae 5 to 11 are disclosed in Korean Patent Application Publication No. 2007-0118711, the disclosures of which are incorporated herein by reference in its entirety.

In the present invention, examples of the compound having a phenanthroline group include compounds that are represented by the following Formulae 12 to 22.

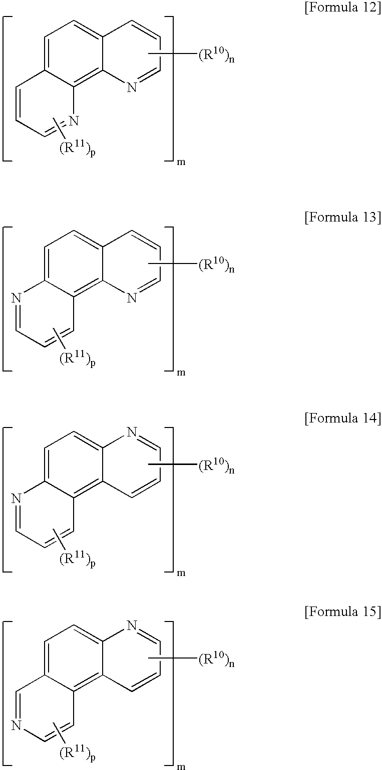

wherein m is an integer of 1 or more, n and p are integers, n+p is 8 or less,

when m is 1, R¹⁰ and R¹¹ are each one selected from the group consisting of hydrogen, an alkyl group such as methyl and ethyl, a cycloalkyl group such as cyclohexyl and a norbornyl, an aralkyl group such as benzyl group, an alkenyl group such as vinyl and allyl, a cycloalkenyl group such as cyclopentadienyl and cyclohexenyl, an alkoxy group such as methoxy, an alkylthio group in which an oxygen atom in ether bonding of an alkoxy group is substituted by a sulfur atom, an arylether group such as phenoxy, an arylthioether group in which an oxygen atom in ether bonding of an arylether group is substituted by a sulfur atom, an aryl group such as phenyl, naphthyl and biphenyl, a heterocyclic group such as furyl, thienyl, oxazolyl, pyridyl, quinolyl, carbazolyl, halogen, a cyano group, an aldehyde group, a carbonyl group, a carboxyl group, an ester group, a carbamoyl group, an amino group, a nitro group, a silyl group such as trimethylsilyl, a siloxanyl group having silicon by ether bonding, and a ring structure that is formed in conjunction with an adjacent group;

when m is 2 or more, R¹⁰ is a direct bond or a group having 2 or more valence of the above-mentioned groups, and R¹¹ is the same as the above-mentioned groups;

the above substituent groups may be unsubstituted or substituted, and the above substitutent groups are the same or different from each other when n or p is 2 or more.

The compounds of Formulae 12 to 15 are disclosed in Korean Patent Application Publication Nos. 2007-0052764 and 2007-0118711, the disclosures of which are incorporated herein by reference in its entirety.

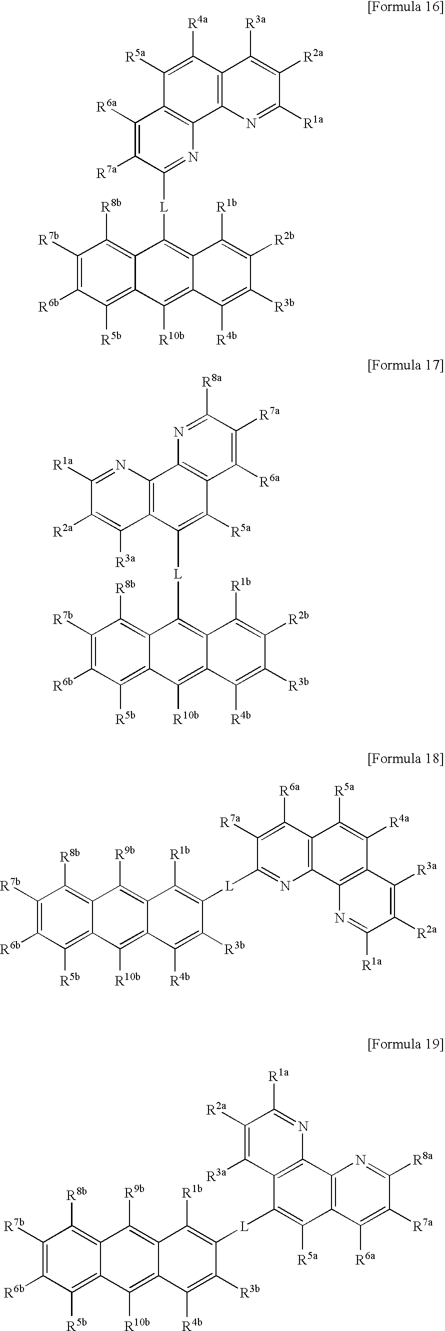

In the Formulae 16 to 19, R^{1a} to R^{8a} and R^{1b} to R^{10b} are independently selected from the group consisting of a hydrogen atom, a substituted or unsubstituted aryl group having 5-60 nuclear atoms, a substituted or unsubstituted pyridyl group, a substituted or unsubstituted quinolyl group, a substituted or unsubstituted alkyl group having 1-50 carbon atoms, a substituted or unsubstituted cycloalkyl group having 3-50 carbon atoms, a substituted or unsubstituted aralkyl group having 6˜50 nuclear atoms, a substituted or unsubstituted alkoxy group having 1-50 carbon atoms, a substituted or unsubstituted aryloxy group having 5-50 nuclear atoms, a substituted or unsubstituted arylthio group having 5-50 nuclear atoms, a substituted or unsubstituted alkoxycarbonyl group having 1-50 carbon atoms, an amino group substituted by a substituted or unsubstituted aryl group having 5-50 nuclear atoms, a halogen atom, a cyano group, a nitro group, a hydroxyl group and a carboxyl group, wherein the substituents are bonded each other to form an aromatic group; and L is a substituted or unsubstituted arylene group having 6-60 carbon atoms, a substituted or unsubstituted pyridynylene group, a substituted or unsubstituted quinolinylene group, or a substituted or unsubstituted fluorenylene group. The compounds of Formulae 16-19 are disclosed in Japanese Patent Application Publication No. 2007-39405, the disclosures of which are incorporated herein by reference in its entirety.

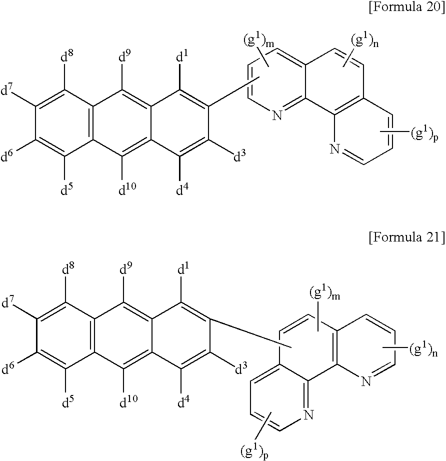

In the Formulae 20 and 21, d¹, d³ to d¹⁰ and g¹ are independently selected from the group consisting of a hydrogen atom and an aromatic or aliphatic hydrocarbon group, m and n are integers of 0 to 2, p is an integer of 0 to 3. The compounds of Formulae 20 and 21 are disclosed in U.S. Patent Application Publication No. 2007/0122656, the disclosures of which are incorporated herein by reference in its entirety.

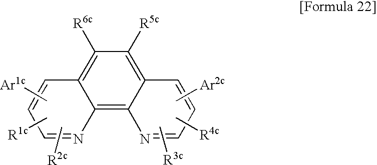

In the Formula 22, R^{1c} to R^{6c} are independently selected from the group consisting of a hydrogen atom, a substituted or unsubstituted alkyl group, a substituted or unsubstituted aralkyl group, a substituted or unsubstituted aryl group, a substituted or unsubstituted heterocyclic group and a halogen atom, and Ar^{1c} and Ar^{2c} are independently selected from the following formulae:

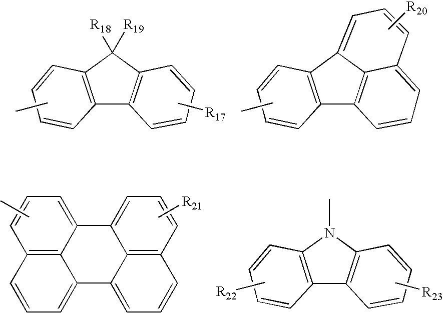

wherein R₁₇ to R₂₃ are independently selected from the group consisting of a hydrogen atom, a substituted or unsubstituted alkyl group, a substituted or unsubstituted aralkyl group, a substituted or unsubstituted aryl group, a substituted or unsubstituted heterocyclic group and a halogen atom. The compound of Formula 22 is disclosed in Japanese Patent Application Publication No. 2004-107263, the disclosures of which are incorporated herein by reference in its entirety.

In the present invention, the n-doped organic compound layer can be formed by a known method in the art, but the scope of the present invention is not limited to a specific method.

FIG. 3 illustrates the organic light emitting device according to an embodiment of the invention.

Referring to FIG. 3, the organic light emitting device may include a substrate 31, an anode 32 on the substrate 31, a p-type hole injection layer (HIL) 33 that is formed on the anode 32 and accepts holes from the anode 32, a hole transport layer (HTL) 34 that is formed on the hole injection layer 33 and transports the holes to an emitting layer (EML) 35, the emitting layer 35 that is formed on the hole transport layer 34 and emits light using the holes and electrons, an electron transport layer (ETL) 36 that is formed on the emitting layer 35 and transports the electrons from a cathode 37 to the emitting layer 35, and the cathode 37 that is formed on the electron transport layer 36. The hole transport layer 34, the emitting layer 35, and the electron transport layer 36 may be formed of the same organic material or different organic materials.

In FIG. 3, the anode 32 transports the holes to the hole injection layer 33, the hole transport layer 34, or the emitting layer 35, and includes a conductive layer 32a and an n-type organic layer 32b. The conductive layer 32a is formed of metal, metal oxides, or conductive polymers. A difference in energy between an LUMO energy level of the n-type organic layer 32b and a Fermi energy level of the conductive layer 32a is about 4 eV or less. A difference in energy between the LUMO energy level of the n-type organic layer 32b and an HOMO energy level of the p-type hole injection layer 33 is about 1 eV or less, and preferably about 0.5 eV or less. An NP junction is formed between the n-type organic layer 32b of the anode 32 and the p-type hole injection layer 33.

According to another embodiment of the invention, the organic light emitting device may include a substrate 31, an anode 32 that is formed on the substrate 31, a p-type hole transport layer 34 that is formed on the anode 32, an emitting layer 35 that is formed on the hole transport layer 34, an electron transport layer 36 that is formed on the emitting layer 35, and a cathode 37 that is formed on the electron transport layer 36. The emitting layer 35 and the electron transport layer 36 may be formed of the same organic material or different organic materials.

According to another embodiment of the invention, the organic light emitting device may include a substrate 31, an anode 32 that is formed on the substrate 31, a p-type emitting layer 35 that is formed on the anode 32, an electron transport layer 36 that is formed on the emitting layer 35, and a cathode 37 that is formed on the electron transport layer 36. The electron transport layer 36 may be formed of organic material.

In the another embodiment of the invention, when the hole transport layer 34 or the emitting layer 35 is formed of the p-type organic material, a difference in energy between the LUMO energy level of the n-type organic layer 32b and the HOMO energy level of the p-type hole transport layer 34 or the p-type emitting layer 35 is about 1 eV or less, and preferably about 0.5 eV or less. An NP junction is formed between the n-type organic layer 32b of the anode 32 and the p-type hole transport layer 34 or the p-type emitting layer 35.

If the difference in energy between the LUMO energy level of the n-type organic layer 32b and the Fermi energy level of the conductive layer 32a is more than 4 eV, a surface dipole or gap state effect to an energy barrier for injection of the holes into the p-type hole injection layer 33 is reduced. If the difference in energy between the LUMO energy level of the n-type organic layer 32b and the HOMO energy level of the p-type hole injection layer 33 is more than 1 eV, the holes or the electrons are not easily formed from the p-type hole injection layer 33 or the n-type organic layer 32b, and driving voltage for injection of the holes is increased.

FIG. 4 illustrates ideal energy level of the known organic light emitting device. At the energy level, loss of energy for injection of the holes and the electrons from the anode and the cathode is minimized. FIG. 5 illustrates energy level of the organic light emitting device according to the embodiment of the invention.

With reference to FIG. 5, the organic light emitting device according to another embodiment of the invention includes the anode having the conductive layer and the n-type organic layer (see FIG. 3), the p-type hole injection layer (HIL), the hole transport layer (HTL), the emitting layer (EML), the electron transport layer (ETL), and the cathode. The difference in energy between the LUMO energy level of the n-type organic layer of the anode and the Fermi energy level of the conductive layer of the anode is about 4 eV or less, and the difference in energy between the LUMO energy level of the n-type organic layer of the anode and the HOMO energy level of the p-type hole injection layer is about 1 eV or less. Since the energy barrier for injection of the holes/electrons is lowered by the n-type organic layer of the anode, the holes are easily transported from the anode to the emitting layer using the LUMO energy level of the n-type organic layer of the anode and the HOMO energy level of the p-type hole injection layer.

In the invention, since the n-type organic layer of the anode lowers the energy barrier for injection of the holes from the anode to the p-type hole injection layer, the p-type hole transport layer, or the p-type emitting layer, the conductive layer of the anode may be formed of various conductive materials. For example, the conductive layer may be formed of the same material as the cathode. In case the anode is formed of the same material as the cathode, the organic light emitting device where conductive material has a low work function may be produced.

Since the cathode and the anode may be formed of the same material, as shown in FIG. 6, a stack-type organic light emitting device having the structure that is equivalent to the structure where two or more organic light emitting device units including an organic layer 73 interposed between an anode 71 and a cathode 75 are connected in series may be produced as shown in FIG. 7. The anode 71 includes a conductive layer and an n-type organic layer.

Referring to FIG. 7, the stack-type organic light emitting device according to the invention has a structure where a plurality of repeating units of an organic layer 83 and a middle conductive layer 85 interposed between an anode 81 and a cathode 87 are layered. The anode 81 and the middle conductive layer 85 include a conductive layer and an n-type organic layer. Preferably, the conductive layer is formed of the transparent material that has a work function similar to that of the cathode 87 and visible ray transmissivity of 50% or more. In case opaque metal is used as the material of the conductive layer, it is necessary for the conductive layer to be made thin so that the conductive layer is almost transparent. Examples of the opaque metal may include Al, Ag, Cu, etc. Particularly, in case Al metal forms the conductive layer of the middle conductive layer 85, the conductive layer has a thickness of about 5 to 10 nm. In the case of the stack-type organic light emitting device, luminance is increased in proportion to the number of organic light emitting device units stacked at the same driving voltage. Accordingly, if the organic light emitting device is formed in the stack type, it is possible to produce the organic light emitting device having high luminance.

Hereinafter, layers constituting the organic light emitting device according to the embodiment of the invention will be described in detail. The layers as described below may be formed of the single material or a mixture of two or more materials.

Anode

The anode injects the holes into the p-type organic layer, such as the hole injection layer, the hole transport layer, or the emitting layer. The anode includes the conductive layer and the n-type organic layer. The conductive layer includes metal, metal oxides, or conductive polymers. The conductive polymers may include electroconductive polymers.

Since the n-type organic layer lowers the energy barrier for injection of the holes from a first electrode to the p-type organic layer, the conductive layer may be formed of various conductive materials. For example, the conductive layer has a Fermi energy level of about 3.5 to 5.5 eV. Examples of the conductive material include carbon, aluminum, vanadium, chromium, copper, zinc, silver, gold, other metals, and alloys thereof; zinc oxides, indium oxides, tin oxides, indium tin oxides (ITO), indium zinc oxides, and metal oxides that are similar thereto; and mixtures of oxides and metals, such as ZnO:Al and SnO₂:Sb. In case the organic light emitting device is a top emission type, opaque material having excellent reflectivity as well as transparent material may be used as the material of the conductive layer. In the case of a bottom emission type of organic light emitting device, transparent material must be used as the material of the conductive layer. If opaque material is used, the layer must be made thin so that the layer is almost transparent.

The n-type organic layer is interposed between the conductive layer and the p-type organic layer, and injects the holes into the p-type organic layer in a low electric field. The n-type organic layer is selected so that a difference in energy between an LUMO energy level of the n-type organic layer of the anode and a Fermi energy level of the conductive layer of the anode is about 4 eV or less and a difference in energy between the LUMO energy level of the n-type organic layer and an HOMO energy level of the p-type organic layer is about 1 eV or less.

For example, the n-type organic layer has the LUMO energy level of about 4 to 7 eV and electron mobility of about 10⁻⁸ cm²/Vs to 1 cm²/Vs, and preferably 10⁻⁶ cm²/Vs to 10⁻² cm²/Vs. If the electron mobility is less than 10⁻⁸ cm²/Vs, it is not easy to inject the holes from the n-type organic layer to the p-type organic layer. If the electron mobility is more than 1 cm²/Vs, the injection of the holes is effectively performed. However, in this case, since the layer is typically formed of crystalline organic material, it is difficult to apply the layer to the organic light emitting device using noncrystalline organic material.

The n-type organic layer may be formed of material that is capable of being vacuum deposited or used to form a thin film using a solution process. Examples of the n-type organic material include, but are not limited to 2,3,5,6-tetrafluoro-7,7,8,8-tetracyanoquinodimethane (F4TCNQ), fluorine-substituted 3,4,9,10-perylenetetracarboxylic dianhydride (PTCDA), cyano-substituted PTCDA, naphthalenetetracarboxylic dianhydride (NTCDA), fluorine-substituted NTCDA, cyano-substituted NTCDA, or hexanitrile hexaazatriphenylene (HAT).

Hole Injection Layer (HIL) or Hole Transport Layer (HTL)

The hole injection layer or the hole transport layer may be formed of the p-type organic layer interposed between the anode and the cathode. Since the p-type hole injection layer or the p-type hole transport layer and the n-type organic layer form an NP junction, the holes formed due to the NP junction are transported through the p-type hole injection layer or the p-type hole transport layer to the emitting layer.

The difference in energy between the HOMO energy level of the p-type hole injection layer or the p-type hole transport layer and the LUMO energy level of the n-type organic layer is about 1 eV or less, and preferably about 0.5 eV or less. Examples of the p-type hole injection layer or the p-type hole transport layer include, but are not limited to arylamine-based compounds, conductive polymers, or block copolymers having both a conjugated portion and an unconjugated portion.

Emitting Layer (EML)

In the emitting layer, the hole transportation and the electron transportation simultaneously occur. Thus, the emitting layer may have both n-type and p-type characteristics. For convenience, the emitting layer may be defined as the n-type emitting layer in case the electron transportation is faster than the hole transportation, and also defined as the p-type emitting layer in case the hole transportation is faster than the electron transportation.

In the n-type emitting layer, since the electron transportation is faster than the hole transportation, light emission occurs at the interface between the hole transport layer and the emitting layer. Accordingly, if the LUMO energy level of the hole transport layer is higher than the LUMO energy level of the emitting layer, higher light emission efficiency may be assured. Examples of the n-type emitting layer include, but are not limited to aluminum tris(8-hydroxyquinoline) (Alq₃); 8-hydroxyquinoline beryllium (BAlq); a benzoxazole-based compound, a benzthiazol-based compound, or a benzimidazole-based compound; a polyfluorene-based compound; and a silacyclopentadiene (silole)-based compound.

In the p-type light emitting layer, hole transport is rapider than electron transport, and thus light emission is made in the vicinity of an interface between the electron transport layer and the light emitting layer. Accordingly, if the HOMO energy level of the electron transport layer is lower than the HOMO energy level of the light emitting layer, higher light emission efficiency can be obtained.

In case of using the p-type light emitting layer, an increase effect of light emission efficiency by a change in LUMO energy level of the hole transport layer is smaller as compared to the case where an n-type light emitting layer is used. Accordingly, in case of using the p-type light emitting layer, it is possible to manufacture an organic light emitting device having an NP junction structure between the n-type organic compound layer and the p-type light emitting layer, without using a hole injection layer and a hole transport layer. The p-type light emitting layer includes, but not limited to, a carbazole-based compound, an anthracene-based compound, a polyphenylenevinylene (PPV)-based polymer, or a spiro compound.

Electron Transport Layer (ETL)

As a material for the electron transport layer, a material having large electron mobility so as to receive electrons from a cathode and transport the electrons to the light emitting layer is preferably used. Examples of the electron transport layer includes, but are not limited to aluminum tris-(8-hydroxyquinoline) (Alq₃), an organic compound comprising Alq₃ structure, or a hydroxy flavone-metal complex compound or a silacyclopentadiene (silole)-based compound.

Cathode

As a material for the cathode, a material having a low work function in order to easily inject electrons into the organic compound layer, such as the hole transport layer or the electron transport layer, is preferably used. The cathode includes, but not limited to, a metal, such as magnesium, calcium, sodium, potassium, titanium, indium, yttrium, lithium, gadolinium, aluminum, silver, tin, and lead or an alloy thereof, or a multilayered material, such as LiF/Al or LiO₂/Al. The cathode can be formed of the same material to the conductive layer of the anode. Alternatively, the cathode or the conductive layer of the anode may include a transparent material.

### ADVANTAGEOUS EFFECTS

As describe above, the organic light emitting device according to the present invention has a low energy barrier for hole injection and excellent charge transport ability of an organic compound layer for charge transport so as to have excellent device performance, such as efficiency, luminance, or a driving voltage. Further, since various materials can be used as a material for an electrode, a device manufacturing process can be simplified. In addition, since the anode and the cathode can be formed of the same material, a layered organic light emitting device having high luminance can be obtained.

While the disclosure has been described with reference to illustrative embodiments, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to a particular embodiment disclosed as the best mode contemplated for carrying out this disclosure, but that the disclosure will include all embodiments falling within the scope of the appended claims.

### DESCRIPTION OF DRAWINGS

FIGS. 1(a) and 1(b) show an energy level of a first electrode before and after application of an n-type organic compound layer to the first electrode for hole injection in an organic light emitting device according to an illustrative embodiment of the present invention, respectively.

FIG. 2 shows an NP junction formed between an n-type organic compound layer of a first electrode for hole injection and a p-type organic compound layer in the organic light emitting device according to the illustrative embodiment of the present invention.

FIG. 3 is a schematic cross-sectional view showing the organic light emitting device according to the illustrative embodiment of the present invention.

FIG. 4 shows an energy level of an organic light emitting device according to the related art.

FIG. 5 shows an energy level of the organic light emitting device according to the illustrative embodiment of the present invention.

FIGS. 6 and 7 are schematic cross-sectional views showing a stacked organic light emitting device according to another embodiment of the present invention.

FIG. 8 is a graph showing UPS (Ultraviolet Photoelectron Spectrum) data of a gold film and an HAT film disposed on the gold film.

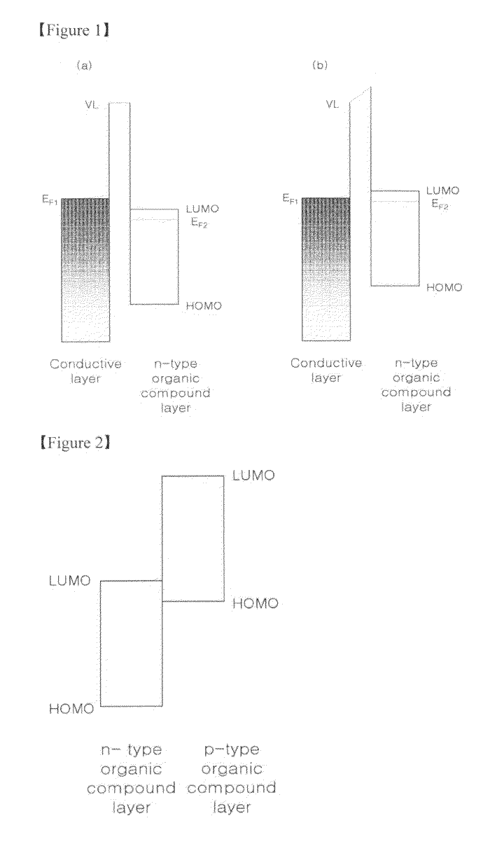

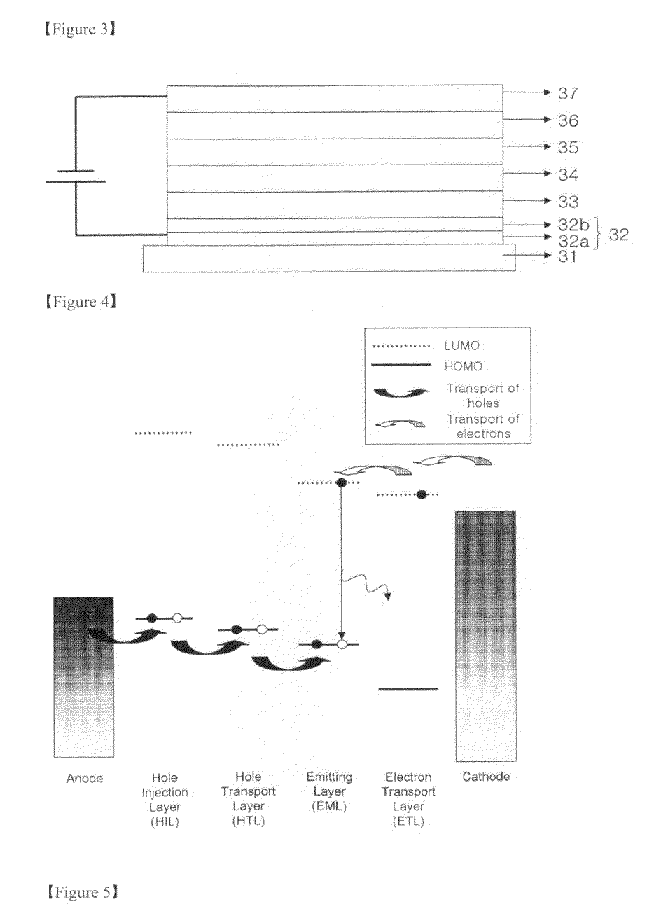

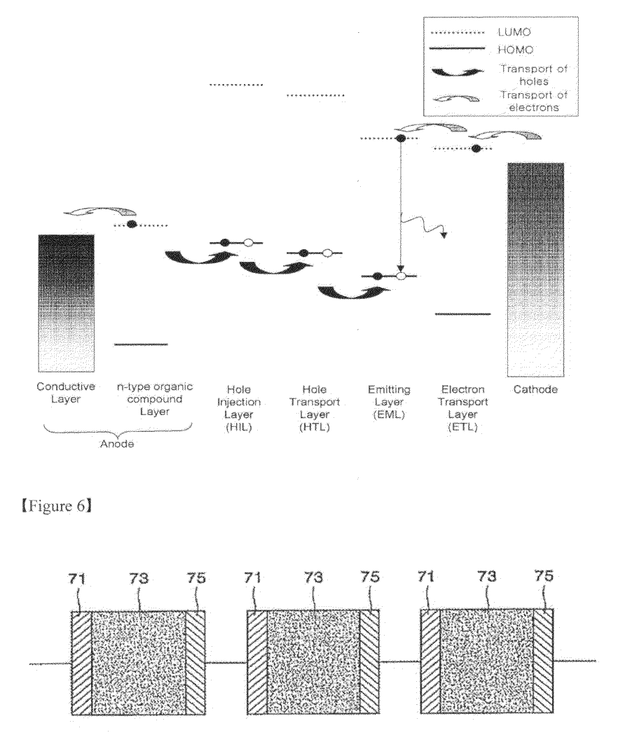

### REFERENCE NUMERALS

31: Substrate
32: Anode
37: Cathode
33: Hole Injection Layer
34: Hole Transport Layer
35: Light Emitting Layer
36: Electron Transport Layer

### MODE FOR INVENTION

A better understanding of the present invention may be obtained in light of the following examples which are set forth to illustrate, but are not to be construed to limit the present invention.

### EXAMPLE

### Example 1

### Measurement of HOMO and LUMO Energy Levels of HAT Using UPS and UV-VIS Absorption Methods

Hexanitrile hexaazatriphenylene (HAT) was used as the organic material having n-type semiconductor characteristics. In order to measure the HOMO level of HAT, a UPS (Ultraviolet photoelectron spectroscopy) method was used. In the method, kinetic energy of electrons that are discharged from a sample when vacuum UV rays (21.20 eV) emitted from the He lamp are radiated onto the sample in a ultravacuum (0 to 8 torr) is analyzed to detect a work function of metal, or to detect ionization energy of organic material, that is, the HOMO level and the Fermi energy level. That is, the kinetic energy of electrons that are discharged from the sample when the vacuum UV rays (21.20 eV) are radiated onto the sample is a difference between 21.2 eV that is vacuum UV energy and electron binding energy of the sample to be measured. Accordingly, a binding energy distribution of molecules in the material of the sample is obtained by analyzing a kinetic energy distribution of electrons discharged from the sample. In connection with this, in case the kinetic energy of the electrons is maximized, the binding energy of the sample has the minimum value. Thereby, the work function (Fermi energy level) and the HOMO level of the sample are determined.

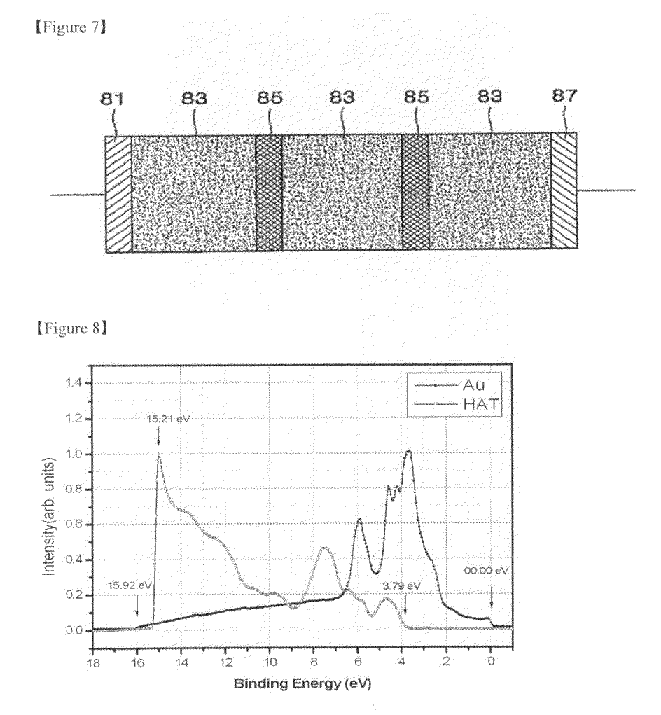

In this example, the work function of gold was measured using the gold film, and the HOMO level of HAT was measured by analyzing the kinetic energy of electrons discharged from HAT material while the HAT material was deposited on the gold film. FIG. 8 illustrates UPS data obtained from the gold film and the HAT film having a thickness of 20 nm on the gold film. Hereinafter, a description will be given using the terminology disclosed in H. Ishii, et al., Advanced Materials, 11, 605-625 (1999).

In FIG. 8, the binding energy (eV) of the x-axis was calculated based on the work function measured from the gold film. That is, in the measurement, the work function of gold was measured, and found to be 5.28 eV that is obtained by subtracting the maximum value (15.92 eV) of binding energy from energy (21.20 eV) of radiated light. The HOMO level of HAT that was obtained by subtracting the difference between the maximum value (15.21 eV) and the minimum value (3.79 eV) of the binding energy from energy of light radiated onto HAT deposited on the gold film was 9.78 eV, and the Fermi energy level was 6.02 V.

Another UV-VIS spectrum was obtained using organic material that was formed by depositing HAT on a surface of glass, and an absorption edge was analyzed, resulting in the finding that the spectrum had a band gap of about 3.26 eV. Thereby, it can be seen that the LUMO of HAT had about 6.54 eV. This value may be changed by exciton binding energy of HAT material. That is, it can be seen that 6.54 eV is larger than the Fermi level (6.02 eV) of the above-mentioned material. The exciton binding energy must be 0.52 eV or more so that the LUMO level is smaller than the Fermi level. Since the exciton binding energy of the organic material typically has 0.5 to 1 eV, it is expected that the LUMO level of HAT has 5.54 to 6.02 eV.

### Example 2

On a glass substrate, an IZO (indium zinc oxide) layer of a thickness of 1000 Å was formed using a sputtering apparatus, then HAT of Formula 2-1 was vacuum deposited on the IZO layer by heating to a thickness of about 500 Å to form a transparent anode having the IZO conductive layer and the n-type organic layer. The HOMO energy level of HAT was about 9.78 eV. Subsequently, NPB of Formula 2-2 was vacuum deposited by heating thereby forming a p-type hole transport layer having a thickness of about 400 Å. Alq₃ (HOMO level=about 5.7 eV) of Formula 2-3 was vacuum deposited on the p-type hole transport layer by heating while doping 6 volume % of the C545T dopant of Formula 2-4 to a thickness of about 300 Å to form the emitting layer.

30 volume % Mg was doped into the compound of Formula 2-5, and vacuum deposited by heating to a thickness of 200 Å to form the electron transport layer on the emitting layer. Aluminum layers having a thickness of 1000 Å were sequentially vacuum deposited on the doped electron transport layer to form the cathode, thereby creating the organic light emitting device. In the above-mentioned procedure, the deposition rate of the organic material was maintained at 0.4 to 0.7 Å/sec, and the deposition rate of aluminum was maintained at about 2 Å/sec. The degree of a vacuum of the deposition chamber was maintained at 2×10⁻⁷ to 5×10⁻⁸ torr during the deposition.

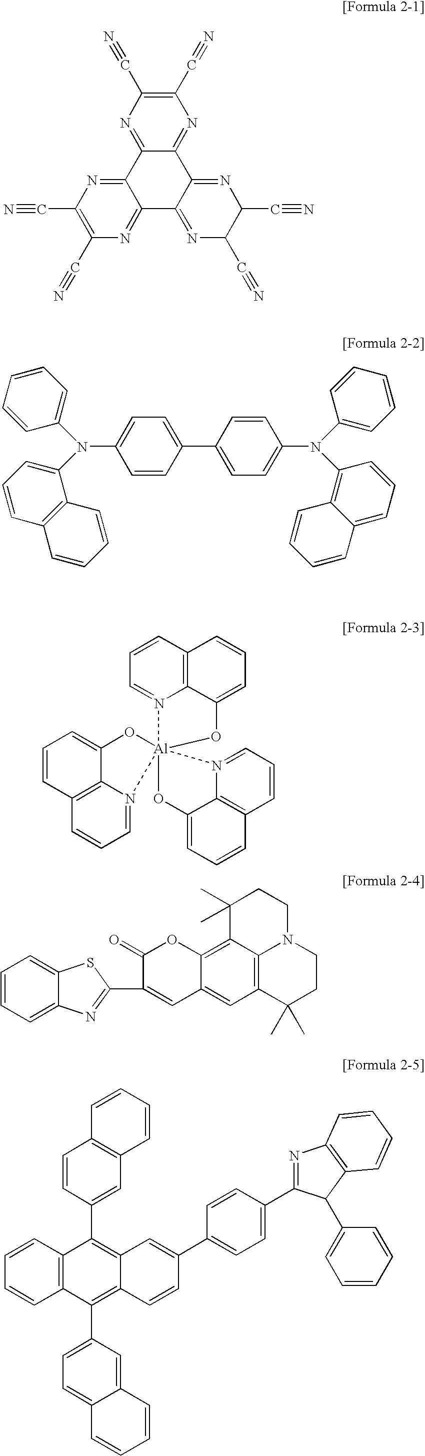

### Example 3

An organic light emitting device was manufactured by using the same method as Example 2, except that the electron transport layer was doped with 10 volume % of Ca instead of Mg.

### Example 4

On a glass substrate, an IZO (indium zinc oxide) layer of a thickness of 1000 Å was formed using a sputtering apparatus. Then, 10 volume % Ca was doped into the compound of Formula 2-5, and vacuum deposited by heating to a thickness of 200 Å to form the electron transport layer on the IZO layer. Alq₃ of Formula 2-3 was vacuum deposited on the electron transport layer by heating while doping 6 volume % of the C545T dopant of Formula 2-4 to a thickness of about 300 Å to form the emitting layer. On the emitting layer, NPB of Formula 2-2 was vacuum deposited by heating thereby forming a p-type hole transport layer having a thickness of about 400 Å. HAT of Formula 2-1 was vacuum deposited on the p-type hole transport layer by heating to a thickness of about 700 Å, on which an IZO (indium zinc oxide) conductive layer of a thickness of 1750 Å was formed using a sputtering apparatus to form a transparent anode having the IZO layer and the HAT n-type organic layer. The HOMO energy level of HAT was about 9.78 eV. In the above-mentioned procedure, the deposition rate of the organic material was maintained at 0.4 to 0.7 Å/sec, and the deposition rate of IZO was maintained at about 0.5 Å/sec. The degree of a vacuum of the deposition chamber was maintained at 2×10⁻⁷ to 5×10⁻⁸ torr during the deposition.

### Comparative Example 1

The procedure of example 2 was repeated to produce the organic light emitting device except that the electron transport layer was not doped with Mg, the layer was formed to a thickness of 200 Å using the compound (HOMO=5.7 eV and LUMO=2.8 eV) of 2-5, and the lithium fluoride LIF thin film having a thickness of 12 Å and the aluminum layer having a thickness of 2500 Å were sequentially vacuum deposited on the electron transport layer to form the cathode. In the above-mentioned procedure, the deposition rate of the organic material was maintained at 0.4 to 0.7 Å/sec, the deposition rate of LiF was maintained at about 0.3 Å/sec, and the deposition rate of aluminum was maintained at about 2 Å/sec. The degree of a vacuum of the deposition chamber was maintained at 2×10⁻⁷ to 5×10⁻⁸ torr during the deposition.

TABLE 1

| | Voltage (V) | Luminance (cd/cm²) |
|---|---|---|
| Example 2 | 3.7 | 970 |
| Example 3 | 3.6 | 980 |
| Example 4 | 3.2 | Top emitting: 380 |
| | | Bottom emitting: 410 |
| Comparative example 1 | 3.8 | 930 |

From Table 1, it can be seen that the device having the electron transport layer doped the alkali earth metal had low driving voltage and high efficiency, compared with the device of Comparative example 1, having LiF instead of having alkali earth metal dopant. From Examples 2 and 3, it can be seen that electron can be injected effectively from the Al electrode when the electron transport layer is doped with alkali earth metal such as Mg or Ca.

In the Example 4, a transparent OLED having inverted structure that had a NP junction structure using n-type organic compound and an electron transport layer doped with alkali earth metal was manufactured. Both anode and cathode of the device were transparent electrodes. From Example 4, it can be seen that electron can be injected effectively into the electron transport layer when the electron transport layer is doped with 10 volume % of alkali earth metal, Ca.

1. An organic light emitting device comprising:
a first electrode;
one or more organic compound layers; and
a second electrode,
wherein the first electrode includes a conductive layer and an n-type organic compound layer disposed on the conductive layer,
a difference in energy between an LUMO energy level of the n-type organic compound layer of the first electrode and a Fermi energy level of the conductive layer of the first electrode is 4 eV or less,
one of the organic compound layers interposed between the n-type organic compound layer of the first electrode and the second electrode is a p-type organic compound layer forming an NP junction along with the n-type organic compound layer of the first electrode,
a difference in energy between the LUMO energy level of the n-type organic compound layer of the first electrode and an HOMO energy level of the p-type organic compound layer is 1 eV or less, and
one or more layers interposed between the conductive layer of the first electrode and the second electrode are n-doped with alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal.

2. The organic light emitting device according to claim 1, wherein the p-type organic compound layer is a hole injection layer, a hole transport layer, or a light emitting layer.

3. The organic light emitting device according to claim 1, further comprising at least one organic compound layer interposed between the p-type organic compound layer and the second electrode.

4. The organic light emitting device according to claim 1, wherein the n-type organic compound layer of the first electrode is formed of an organic material selected from a group consisting of 2,3,5,6-tetrafluoro-7,7,8,8-tetracyanoquinodimethane (F4TCNQ), fluoro-substituted 3,4,9,10-perylenetetracarboxylic dianhydride (PTCDA), cyano-substituted PTCDA, naphthalene-tetracarboxylic-dianhydride (NTCDA), fluoro-substituted NTCDA, cyano-substituted NTCDA, and hexanitrile hexaazatriphenylene (HAT).

5. The organic light emitting device according to claim 1, wherein the conductive layer of the first electrode is formed of a material selected from a group consisting of metal, metal oxide, and conductive polymer.

6. The organic light emitting device according to claim 1, wherein the conductive layer of the first electrode and the second electrode are formed of the same material.

7. The organic light emitting device according to claim 1, wherein at least one of the conductive layer of the first electrode and the second electrode includes a transparent material.

8. The organic light emitting device according to claim 1, wherein the n-type organic compound layer has an LUMO energy ranging from about 4 to 7 eV and electron mobility ranging from about 10⁻⁸ cm²/Vs to 1 cm²/Vs.

9. The organic light emitting device according to claim 1, wherein the n-doped organic compound layer is an electron injection and/or transport layer.

10. A stacked organic light emitting device comprising:
two or more repeating units that each includes a first electrode, one or more organic compound layers, and a second electrode,
wherein the first electrode includes a conductive layer and an n-type organic compound layer disposed on the conductive layer,
a difference in energy between an LUMO energy level of the n-type organic compound layer of the first electrode and a Fermi energy level of the conductive layer of the first electrode is 4 eV or less,
one of the organic compound layers interposed between the n-type organic compound layer of the first electrode and the second electrode is a p-type organic compound layer forming an NP junction along with the n-type organic compound layer of the first electrode,
a difference in energy between the LUMO energy level of the n-type organic compound layer of the first electrode and an HOMO energy level of the p-type organic compound layer is 1 eV or less,
one or more layers interposed between the conductive layer of the first electrode and the second electrode are n-doped with alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal, and
the second electrode of one repeating unit is connected to the first electrode of adjacent repeating units connected in series.

11. The stacked organic light emitting device according to claim 10, wherein the conductive layer of the first electrode and the second electrode located at an interface of repeating units connected in series are formed of a single layer.

12. A method for manufacturing an organic light emitting device, which includes a first electrode, one or more organic compound layers, and a second electrode, comprising:
forming an n-type organic compound layer on a conductive layer so as to form a first electrode;
forming a p-type organic compound layer on the n-type organic compound layer of the first electrode; and
forming one or more layers of the organic compound layers by n-doping using alkali earth metal; an alkali earth metal compound; an alkali metal compound; or La Ce, Pr, Nd, Sm, Eu, Tb, Th, Dy, Ho, Er, Em, Gd, Yb, Lu, Y or Mn, or metal compound containing at least one of the above types of metal.
